(19) United States
(12) Patent Application Publication
(10) Pub. No.: US 2019/0162758 A1
(43) Pub. Date: May 30, 2019

(54) CURRENT-MEASURING APPARATUS, SERIES OF CURRENT-MEASURING APPARATUSES, AND METHOD FOR MEASURING CURRENT

(71) Applicants: Dirk Hertz, Fichtenhof (DE); Florian Ringer, Vilseck (DE)

(72) Inventors: Dirk Hertz, Fichtenhof (DE); Florian Ringer, Vilseck (DE)

(21) Appl. No.: 16/196,123

(22) Filed: Nov. 20, 2018

(30) Foreign Application Priority Data
Nov. 27, 2017 (DE) 102017221173.3

(51) Int. Cl. G01R 15/18; G01R 19/00

(52) U.S. Cl. CPC G01R 15/18; G01R 19/0092

(57) ABSTRACT

The disclosure relates to a current-measuring apparatus having an assembly with two or more burdens in series connection and a current transformer module with a secondary coil. Herein, the series connection includes three or more contacts so that the connection combinations of the secondary coil to in each case two of the three or more contacts enables different groups of one or more burdens to be switched with the secondary coil to form an electric circuit. A secondary current induced by a primary current to be measured in the secondary coil is able to flow through the electric circuit formed in this way.

The application claims the benefit of German Patent Application No. DE 10 2017 221 173.3, filed Nov. 27, 2017, which is hereby incorporated by reference in its entirety.

### TECHNICAL FIELD

The disclosure relates to a current-measuring apparatus, a series of current-measuring apparatuses, and a method for measuring current.

### BACKGROUND

Current transformers are known, such as those described in German Patent Publication No. DE 10 2006 059 384 A1 and International PCT Application Publication No. WO 2012/022377A1. The detection of different operating states, some with very high currents but also some with very low currents, places high requirements on current transformers that accordingly have to be suitable for measuring high and low currents. Current transformers, (which may function based on electric induction), may be used to detect a primary current to be measured which gives rise to a secondary current with a reduced level on the secondary side of the current transformer. Thus, the current transformer is used, on the one hand, for potential separation and, on the other, to reduce the signal level. Herein, the height of the secondary current is, on the one hand, dependent upon the ratio of the number of turns of the windings on the primary side and the secondary side of the current transformer and, on the other, on a burden resistor, which is connected on the output side to the secondary coil and through which the secondary current flows.

Many series of devices used in three-phase systems cover a very wide load range, more accurately: current range. In order to be able to provide the requirements placed on the accuracy of the measured current values over the entire current range, it is necessary to use different current transformers in the series of the devices according to the current range. However, it may not be sufficient merely to adapt the number of turns in the secondary circuit of the current transformers; it also may be necessary to adapt the burden.

German Patent Publication No. DE 3541274 A1 describes a measuring device for detecting the actual current value in a current converter, with a current transformer and a downstream burden. Herein, the burden is constructed as a burden switching mechanism that is variably adjustable to different ohmic resistance values, wherein the burden is adjusted in dependence on the load connected to the current converter. For this purpose, a microcomputer provides a burden required according to a stored combination table in dependence on an input load-type of a current converter by opening and closing the switches of a burden switching mechanism.

However, a burden switching mechanism including a plurality of burdens connected in parallel based on error-free control of a plurality of switches by a microcomputer in accordance with a stored combination table is relatively expensive.

### SUMMARY AND DESCRIPTION

The scope of the present disclosure is defined solely by the appended claims and is not affected to any degree by the statements within this description. The present embodiments may obviate one or more of the drawbacks or limitations in the related art.

The present disclosure is based on the object of providing a current transformer that may be configured to different load ranges in a simple manner.

The object is achieved by a current-measuring apparatus having an assembly with a plurality of burdens (e.g., two or more burdens) in series connection and a current transformer module with a secondary coil. Herein, the series connection includes three or more contacts so that the possible connection combinations of the secondary coil to in each case two of the three or more contacts enables different groups of one or more burdens to be connected to the secondary coil to form an electric circuit through which a secondary current induced in the secondary coil by a primary current to be measured may flow. The object is further achieved by a method for measuring current with the following acts: provision of an assembly with a plurality of burdens in series connection, wherein the series connection includes three or more contacts; provision of a current transformer module with a secondary coil; selection of one of the possible connection combinations in which the secondary coil is connected in each case to two of the three or more contacts such that at least one of the burdens forms an electric circuit with the secondary coil; connection of the secondary coil to two of the three or more contacts in accordance with the selected connection combination; positioning the secondary coil such that secondary current induced in the secondary coil by a primary current to be measured flows through the electric circuit; picking up a voltage that drops across at least two of the two or more burdens connected in series; and calculating a current value of the primary current from the measured voltage.

The series connection includes three or more contacts so that a plurality of connection combinations of the secondary coil to in each case two of the three or more contacts is possible. Each of the connection combinations is used to connect different groups of one or more burdens to the secondary coil to form an electric circuit. This enables the resistors connected to the electric circuit to be interconnected in groups such that the total resistance values of the different groups are configured to different measuring situations.

The current-measuring apparatus may be a current transformer, for example, a toroidal core current transformer. The current-measuring apparatus may be used in three-phase systems to measure the phase currents, for example, in a soft starter. The current-measuring apparatus functions as a special transformer; it has a secondary coil with one or more secondary windings arranged in the vicinity of a primary coil with only one or a few primary windings through which current to be measured flows. Herein, the primary coil may be formed by a current conductor guided through the current transformer which corresponds to a coil with a single winding. The primary current to be measured is reduced proportionally by the ratio of the number of primary winding turns to the number of secondary winding turns. The secondary current of the current transformer flows through the resistor connected to the secondary coil used to measure the current. This resistor is called a burden, transformer burden, or burden resistor. The voltage applied to the burden may be further processed with the available measuring instruments or electronic circuits.

The voltage across the burden may be measured with an electronic control unit and the primary current calculated from this in conjunction with the known variables ‘burden resistance’ and ‘number of primary and secondary windings’.

The disclosure is based on the knowledge that a modular construction of a current-measuring apparatus serving as a current transformer is simple to achieve. A series connection of a plurality of burdens enables the use of different burden resistors with identical assembly equipment.

The functional principle on which the disclosure is based is as follows. The current transformer module is connected, (e.g., via a plug-in connector), to the assembly, for example, in the form of a control plate. The transformer current induced in the secondary coil flows through the one or more burdens. The voltage that drops across all the burdens is measured, e.g., with the aid of a measurand-detection unit. The transformer current flows through different burdens in accordance with the way in which the current transformer module is connected to the assembly, for example, the plug pins to which the secondary coil of the current transformer module is connected.

The high internal resistance of a voltage-measuring device for measuring the voltage that drops across all the burdens causes the ratio of the burden resistance of the burdens of the series connection connected into the electric circuit with the secondary coil to the internal resistance of the voltage-measuring device of the measurand-detection unit to be almost zero. Therefore, the voltage drop across the burdens of the series connection that are not connected into the electric circuit with the secondary coil and through which the secondary current flowing in the electric circuit does not flow is negligible. Therefore, the voltage measured by the measurand-detection unit substantially corresponds to the voltage across the burdens connected into the electric circuit with the secondary coil.

The present disclosure makes it possible to provide a series with a lower number of component parts within the series. To date, assemblies in a series have been equipped with different burdens; therefore, a series included different variants of assemblies. It is now possible to provide a series with one single variant of an assembly.

The variance in equipment is abolished because the assembly is equipped identically. This results in lower costs due to higher quantities per variant, less extensive storekeeping and shorter retrofitting times and lower costs in the placement line, fewer provisioning areas in production, a lower amount of testing and a reduced number of spare part variants. In addition, the danger of confusion during the construction of the device is reduced, e.g., there is less risk of incorrect variants of the assembly being fitted during the construction of the device.

According to an embodiment, the current-measuring apparatus includes a measurand-detection unit with measuring contacts for picking up a voltage that drops across at least two of the two or more burdens. Due to identical device functions, the measurand-detection unit may be the same over a whole series of current-measuring apparatuses. The measurand-detection unit may include an electronic evaluation unit, which is able to evaluate and forward the measured measurands, for example, to a storage unit and/or to an human-machine interface (HMI).

According to an embodiment, the current-measuring apparatus includes a plug-in connector including a plurality of poles for connecting the current transformer modules to the assembly. The use of a multipolar plug-in connection in combination with a plurality of burden resistors in series makes it possible, despite the fact that the assembly for voltage measurement is equipped identically, to use different burden resistors, e.g., connect them into the electric circuit through which the secondary current, (e.g., the transformer current), flows.

The volume of the current transformer module is primarily derived from the primary current to be measured. For series of devices that are also suitable for high primary currents, therefore, the current transformer module does not have to be integrated in the assembly in which the measurand-detection unit may be integrated. In this case, the secondary coil of the current transformer module is connected via a plug-in connector to the assembly, e.g., including a measurand-detection unit and the burdens and/or an electronic control unit.

According to an embodiment, the plurality of burdens (e.g., two or more burdens) connected in series are in each case connected in an electrically conductive manner to two poles of a part of the plug-in connector arranged on the assembly. The use of a multipolar plug-in connector and a different connector-pin assignment with different current transformer modules enables the use of different burden resistors wherein the assembly is equipped identically.

According to an embodiment, the secondary coil of the current transformer module is connected in an electrically conductive manner to two poles of a part of the multipolar plug-in connector arranged on the current transformer module. The use of a multipolar plug-in connection and a different connector-pin assignment with different current transformer modules enables the use of different burden resistors with an assembly that is fitted out identically.

The part of the plug-in connector arranged on the assembly may be embodied as a male connector part, (e.g., a plug or integrated connector), or as a female connector part, (e.g., a coupling or a sleeve). The part of the plug-in connector arranged on the current transformer module is embodied correspondingly to the part of the plug-in connector arranged on the assembly.

According to an embodiment, the series connection includes two or more pairs of burdens with the same electrical resistance, which are arranged symmetrically relative to a point of symmetry of the series connection. Because it is necessary to measure negative voltages or amplitudes due the alternating current to be measured, the voltage of the point of symmetry (e.g., reference point) for the burdens lies between the supply voltage and the ground of the measurand-detection unit, which may include an electronic evaluation unit. Differential evaluation has two advantages. First, voltage fluctuations of the point of symmetry have no influence on measuring accuracy because with differential evaluation both voltages are subtracted relative to the ground of the evaluation unit. Second, the maximum amplitude of the differential signal corresponds to double the value of the amplitude of a single signal. Hence, the resolution of the current measurement is doubled; this improves accuracy.

A further embodiment is a series of current-measuring apparatuses as described above, wherein the assembly may be connected to two or more different current transformer modules and wherein two current-measuring apparatuses in the series, in each case including the assembly and a different current transformer module, differ in at least one burden, which is connected to the secondary coil to form the electric circuit.

### BRIEF DESCRIPTION OF THE DRAWINGS

The following describes the disclosure with reference to several exemplary embodiments with the aid of the attached drawings.

FIG. 1 depicts a first variant of a current-measuring apparatus.

FIG. 2 depicts another variant of a current-measuring apparatus.

FIG. 3 depicts a further variant of a current-measuring apparatus.

FIG. 4 depicts a series of current-measuring apparatuses.

FIG. 5 depicts a first variant of a current-measuring apparatus with symmetrically arranged burdens.

FIG. 6 depicts another variant of a current-measuring apparatus with symmetrically arranged burdens.

FIG. 7 depicts a variant of a current-measuring apparatus with an extended number of burdens.

### DETAILED DESCRIPTION

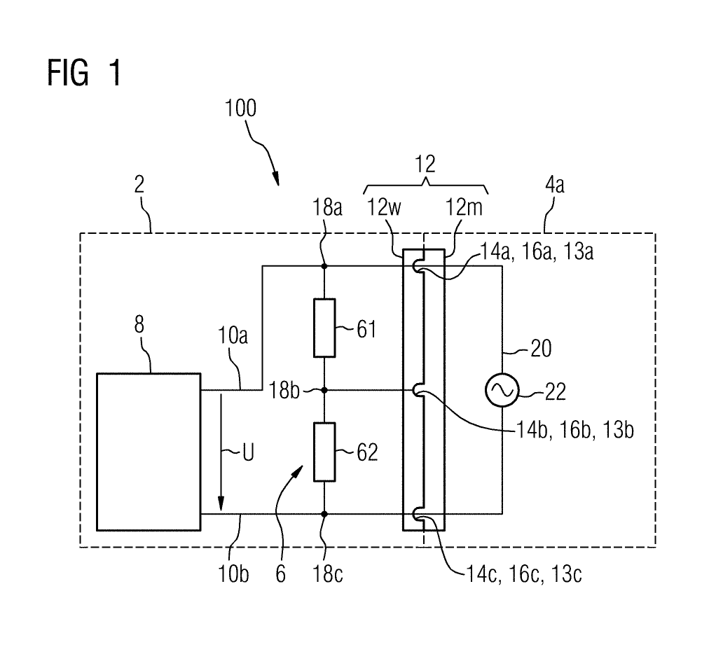

FIGS. 1 to 3 depict three different connection combinations of a secondary coil 20 and a series connection 6 of burdens 61, 62.

FIG. 1 depicts a first embodiment of a current-measuring apparatus 100. The current-measuring apparatus 100 includes an assembly 2 with two burdens 61, 62 in series connection 6. The series connection 6 includes a first burden 61 between a first contact point 18a and a second contact point 18b and a second burden 62 between the second contact point 18b and a third contact point 18c. The current-measuring apparatus 100 also includes a current transformer module 4a with a secondary coil 20. The terms contact and contact point are used synonymously in the description.

The current-measuring apparatus 100 also includes a plug-in connector 12 including three poles 13a, 13b, 13c with the aid of which the current transformer module 4a is connected detachably to the assembly 2 in a plugging process. The poles 13a, 13b, 13c in each case include a contact pin 14a, 14b, 14c on a male part 12m of the plug-in connector 12 and a contact hole 16a, 16b, 16c on a female part 12w of the plug-in connector 12. The three poles 13a, 13b, 13c include two outer poles 13a, 13c and a middle pole 13b arranged on the plug-in connector 12 between the two outer poles 13a, 13c.

Herein, the secondary coil 20 of the current transformer module 4a is connected in an electrically conductive manner to the contact pins 14a, 14c of the outer poles 13a, 13c of the plug-in connector 12. The three contact points 18a, 18b and 18c of the series connection 6 are in each case connected in an electrically conductive manner to a contact hole 16a, 16b, 16c of the three poles 13a, 13b, 13c of the plug-in connector 12. Herein, the first contact point 18a is electrically connected to a contact hole 16a of the first outer pole 13a, the second contact point 18b is electrically connected to the contact hole 16b of the middle pole 13b and the third contact point 18c is electrically connected to the contact hole 16c of the second outer pole 13c. The connection of the male part 12m of the plug-in connector 12 to the female part 12w of the plug-in connector 12 in a plugging process causes the secondary coil 20 to be electrically connected to the series connection 6 including the two burdens 61, 62 so that the secondary coil 20 and the group of burdens including the two burdens 61, 62 of the series connection 6 form an electric circuit. Hence, a first connection combination of the secondary coil 20 and the series connection 6 is implemented.

Hence, secondary current 22 induced in the secondary coil 20 by a primary current to be measured is able to flow through this electric circuit. To enable a secondary current 22 to be induced in the secondary coil 20 by a primary current, the secondary coil 20 is positioned in spatial proximity to a primary coil conducting the primary current.

A voltage U that drops across the two burdens 61, 62 of the electric circuit, the so-called burden voltage, is picked up in that the first contact point 18a is connected via a first measuring contact 10a to a first input of a measurand-detection unit 8 and the third contact point 18c via a second measuring contact 10b to a second input of a measurand-detection unit 8. Herein, the voltage value U may be supplied to a voltage-measuring device of the measurand-detection unit 8 and the current value I_1 of the primary current determined therefrom. The relationship between the burden voltage U, the current value I_1 of the primary current, the electrical resistance R_2 of burden series connection 61, 62 and the number of turns n_1 or n_2 of the primary coil or the secondary coil 20 is as follows:

U=I_1·(n_1/n_2)·R_2

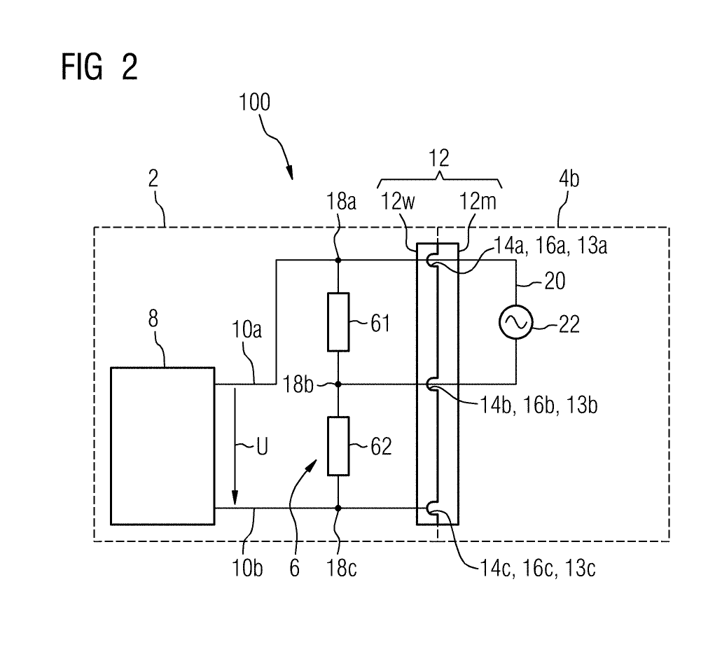

FIG. 2 depicts a further embodiment of a current-measuring apparatus 100, including an assembly 2, a current transformer module 4b, and a plug-in connector 12 including three poles 13a, 13b, 13c. The assembly 2 shown in FIG. 2 is embodied identically to the assembly 2 depicted in FIG. 1. Therefore, reference is made to the description of the assembly 2 in FIG. 1 with respect to the assembly 2 shown in FIG. 2. The same applies with respect to the female part 12w of the plug-in connector 12 arranged on the assembly 2.

The current-measuring apparatus 100 shown in FIG. 2 differs from the current-measuring apparatus 100 shown in FIG. 1 in the current transformer module 4b and in the male part 12m of the plug-in connector 12 arranged on the current transformer module 4b. Herein, the secondary coil 20 of the current transformer module 4b is connected in an electrically conductive manner to the contact pins 14a, 14b of a first outer pole 13a and the middle pole 13b of the plug-in connector 12.

The connection of the male part 12m of the plug-in connector 12 to the female part 12w of the plug-in connector 12 causes the secondary coil 20 to be electrically connected to the first burden 62 of the series connection 6 including the two burdens 61, 62 such that the secondary coil 20 and the first burden 61 arranged between the first contact point 18a and the second contact point 18b form an electric circuit. Hence, a second connection combination of the secondary coil 20 and the series connection 6 is implemented.

Hence, a secondary current 22 induced in the secondary coil 20 by a primary current to be measured is able to flow through this electric circuit. To enable a secondary current 22 to be induced in the secondary coil 20 by a primary current, the secondary coil 20 is positioned in spatial proximity to a primary coil conducting the primary current.

A voltage U that drops across the first burden 61 of the electric circuit, the so-called burden voltage, is picked up in that the first contact point 18a is connected to a first input of a measurand-detection unit 8 and the third contact point 18c with a second input of a measurand-detection unit 8. Herein, the voltage value U may be supplied to a voltage-measuring device of the measurand-detection unit 8 and the current value I_1 of the primary current determined therefrom.

Voltage-measuring devices have particularly high internal resistance. This guarantees that no current that would influence the properties of the circuit to be measured, and hence the measurement, flows through the voltage-measuring devices. The high internal resistance of the voltage-measuring device causes the ratio of the burden resistance of the first burden 61 to the internal resistance of the voltage-measuring device of the measurand-detection unit 8 to be almost zero; hence, the voltage drop across the second burden 62 of the series connection 6 to which the secondary current 22 flowing in the electric circuit is not applied is negligible. Therefore, the voltage U measured by the measurand-detection unit 8 corresponds to the voltage across the first burden 61 used.

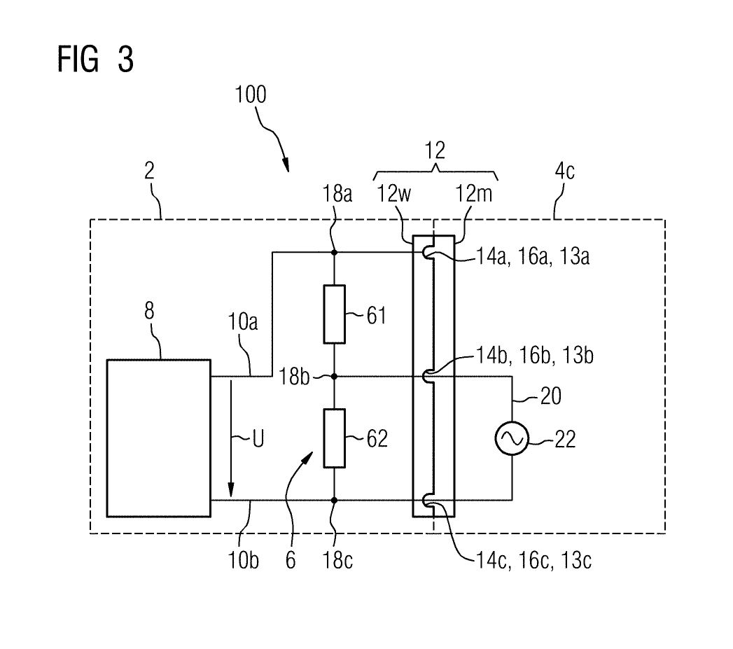

FIG. 3 depicts a further embodiment of a current-measuring apparatus 100 including an assembly 2, a current transformer module 4c, and a plug-in connector 12 including three poles 13a, 13b, 13c. The assembly 2 shown in FIG. 3 is identical to the assembly 2 depicted in FIG. 1; therefore, reference is made to the description of the assembly 2 in FIG. 1 with respect to the assembly 2 shown in FIG. 3. The same applies with respect to the female part 12w of the plug-in connector 12 arranged on the assembly 2.

The current-measuring apparatus 100 shown in FIG. 3 differs from the current-measuring apparatus 100 shown in FIG. 1 in the current transformer module 4c and in the male part 12m of the plug-in connector 12 arranged on the current transformer module 4c: Herein, the secondary coil 20 of the current transformer module 4c is connected in an electrically conductive manner to the contact pins 14b, 14c of the middle pole 13b and a second outer pole 13c of the plug-in connector 12.

The connection of the male part 12m of the plug-in connector 12 to the female part 12w of the plug-in connector 12 causes the secondary coil 20 to be electrically connected to the second burden 62 of the series connection 6 including the two burdens 61, 62 such that the secondary coil 20 and the second burden 62 arranged between the second contact point 18b and the third contact point 18c form an electric circuit. Hence, a third connection combination of the secondary coil 20 and the series connection 6 is implemented.

Hence, a secondary current 22 induced in the secondary coil 20 by a primary current to be measured is able to flow through this electric circuit. To enable a secondary current 22 to be induced in the secondary coil 20 by a primary current, the secondary coil 20 is positioned in spatial proximity to a primary coil conducting the primary current. A voltage U that drops across the second burden 62 of the electric circuit, the so-called burden voltage, is picked up in that the first contact point 18a is connected to a first input of a measurand-detection unit 8 and the third contact point 18c to a second input of a measurand-detection unit 8. Herein, the voltage value U may be supplied to a voltage-measuring device of the measurand-detection unit 8 and the current value I_1 of the primary current determined therefrom.

Voltage-measuring devices have particularly high internal resistance. This guarantees that no current that would influence the properties of the circuit to be measured, and hence the measurement, flows through the voltage-measuring devices. The high internal resistance of the voltage-measuring device causes the ratio of the burden resistance of the second burden 62 to the internal resistance of the voltage-measuring device of the measurand-detection unit 8 to be almost zero. Hence, the voltage drop across the first burden 61 of the series connection 6 to which the secondary current 22 flowing in the electric circuit is not applied is negligible. Therefore, the voltage U measured by the measurand-detection unit 8 corresponds to the voltage across the second burden 62 used.

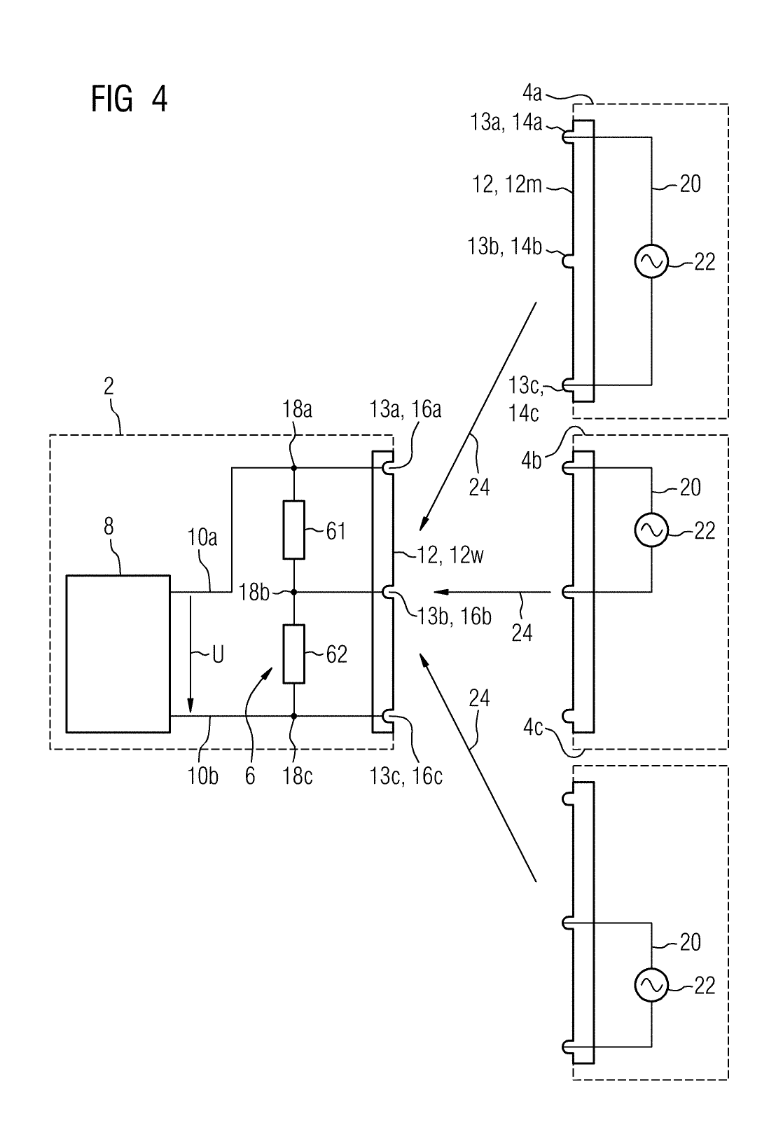

FIG. 4 depicts a series of current-measuring apparatuses 100 with which three different connection combinations of a secondary coil 20 and a series connection 6 of burdens 61, 62 may be implemented. The current-measuring apparatuses 100 in the series in each case include an identical assembly 2 to that described in FIG. 1 and a different current transformer module 4a, 4b, 4c to that described in FIGS. 1 to 3. This enables an assembly 2 to be connected 24 to two or more different current transformer modules 4a, 4b, 4c. The connection 24 between the assembly 2 and the current transformer module 4a, 4b, 4c is provided by a plug-in connector 12 including a plurality of poles 13a, 13b, 13c.

Two current-measuring apparatuses 100 in the series, in each case including an assembly 2 and a different current transformer module 4a, 4b, 4c, differ in at least one burden 61, 62, which is connected to the secondary coil 20 to form the electric circuit. For example, in a first current transformer module 4a, the secondary coil 20 is connected to a first contact pin 14a and a third contact pin 14c, in a second current transformer module 4b, the secondary coil 20 is connected to a first contact pin 14a and a second contact pin 14b, and, in a third current transformer module 4a, the secondary coil 20 is connected to a second contact pin 14b and a third contact pin 14c. Accordingly, due to the use of identical assemblies 2 with an identical internal wiring of the series connection 6 a), when the first current transformer module 4a is plugged 24 onto the assembly 2, both burdens 61, 62 are connected to the electrical circuit, b), when the second current transformer module 4b is plugged onto the assembly 2, the first burden 61 is connected to the electrical circuit and c), when the third current transformer module 4c is plugged onto the assembly 2, the second burden 62 is connected to the electrical circuit.

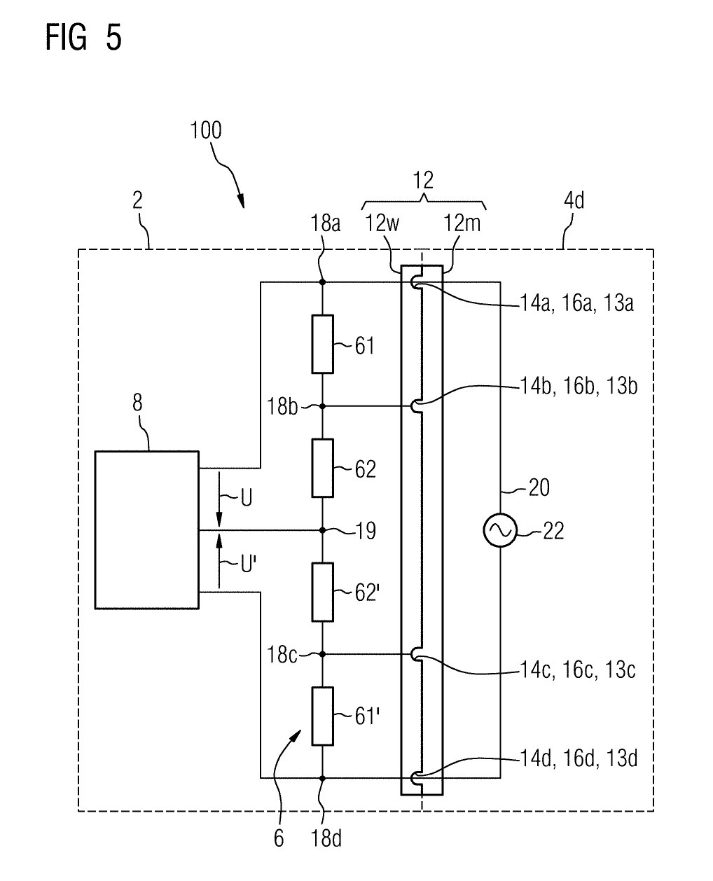

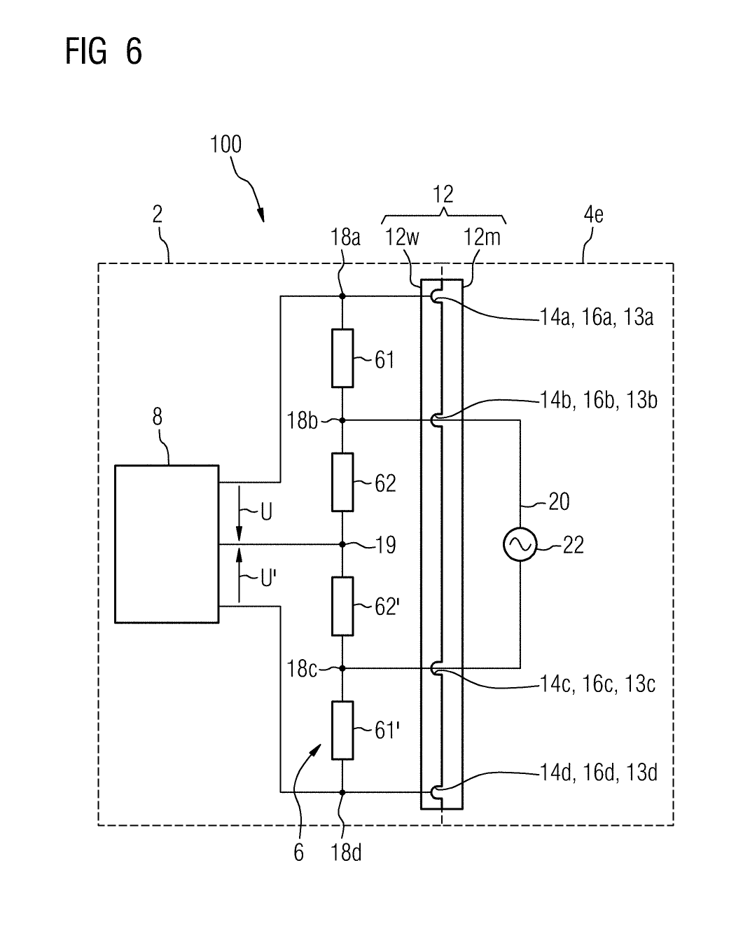

FIGS. 5 and 6 depict two different connection combinations of current-measuring apparatus 100 with symmetrically arranged burdens.

The current-measuring apparatus 100 includes an assembly 2 with four burdens 61, 61′, 62, 62′ in series connection 6. The series connection 6 includes a first burden 61 between a first contact point 18a and a second contact point 18b and a second burden 62 between the second contact point 18b and a point of symmetry 19. The series connection 6 also includes a third burden 62′ that is identical to the second burden 62 between the point of symmetry 19 and a third contact point 18c and a fourth burden 61′ that is identical to the first burden 61 between the third contact point 18c and a fourth contact point 18d. Hence, the burdens 61, 61′, 62, 62′ of the series connection 6 are arranged symmetrically relative to the point of symmetry 19.

The current-measuring apparatus 100 further includes a current transformer module 4d, 4e with a secondary coil 20.

The current-measuring apparatus 100 further includes a plug-in connector 12 including four poles 13a, 13b, 13c, 13d with the aid of which the current transformer module 4d, 4e is connected detachably to the assembly 2. The poles 13a, 13b, 13c, 13d in each case include a contact pin 14a, 14b, 14c, 14d on a male part 12m of the plug-in connector 12 and a contact hole 16a, 16b, 16c, 16d on a female part 12w of the plug-in connector 12. The four poles 13a, 13b, 13c, 13d include two outer poles 13a, 13d and two inner poles 13b, 13c, wherein the two inner poles 13b, 13c on the plug-in connector 12 are arranged between the two outer poles 13a, 13d.

The first two contacts 18a, 18b and the last two contact points 18c and 18d of the series connection 6 are in each case connected to a contact hole 16a, 16b, 16c, 16d of the four poles 13a, 13b, 13c, 13d of the plug-in connector 12 in an electrically conductive manner. Herein, the first contact point 18a is electrically connected to a contact hole 16a of the first outer pole 13a, the second contact point 18b is electrically connected to the contact hole 16b of the first inner pole 13b, the third contact point 18c is electrically connected to the contact hole 16c of the second inner pole 13c and the fourth contact point 18d is electrically connected to the contact hole 16d of the second outer pole 13d.

Herein in a first connection combination of the current-measuring apparatus 100 shown in FIG. 5, the secondary coil 20 of the current transformer module 4d is connected in an electrically conductive manner to the contact pins 14a, 14d of the two outer poles 13a, 13d of the plug-in connector 12. The connection of the male part 12m of the plug-in connector 12 to the female part 12w of the plug-in connector 12 causes the secondary coil 20 to be electrically connected to the series connection 6 including the four burdens 61, 62, 61′, 62′ so that the secondary coil 20 and the four burdens 61, 62, 61′, 62′ form an electric circuit. Hence, a secondary current 22 induced in the secondary coil 20 by a primary current to be measured is able to flow through this electric circuit. A voltage U that drops across the first 61 and second 62 burden of the electric circuit is picked up in that the first contact point 18a is connected a first input of a measurand-detection unit 8 and the point of symmetry 19 to a reference potential input of a measurand-detection unit 8. A voltage U′ that drops across the third 62′ and fourth 61′ burden of the electric circuit is picked up in that the fourth contact point 18d is connected to a second input of the measurand-detection unit 8 and measured against the potential of the reference potential inputs. Hence, a difference voltage measurement is performed with which the difference voltage between the symmetrically arranged halves of the series connection 6 is measured.

On the other hand, in a second connection combination of the current-measuring apparatus 100 shown in FIG. 6, the secondary coil 20 of the current transformer modules 4e shown in FIG. 6 are connected in an electrically conductive manner to the contact pins 14b, 14c of the two inner poles 13b, 13c of the plug-in connector 12. The connection of the male part 12m of the plug-in connector 12 to the female part 12w of the plug-in connector 12 causes the secondary coil 20 to be electrically connected to the two burdens 62, 62′ arranged in the middle part of the series connection 6 so that the secondary coil 20 and the two burdens 62, 62′ form an electric circuit.

Hence, in both connection combinations, secondary current 22 induced in the secondary coil 20 by a primary current to be measured is able to flow through the electric circuit of the current-measuring apparatus 100. The first contact point 18a is connected to a first input of a measurand-detection unit 8, the fourth contact point 18e is connected to a second input of the measurand-detection unit 8 and the point of symmetry 19 of the series connection 6 to a reference potential input of the measurand-detection unit 8.

In the connection combination of the current-measuring apparatus 100 shown in FIG. 5, a differential voltage measurement is performed in that the voltage U that drops across the first 61 and second 62 burden of the electric circuit and the voltage U′ that drops across the third 62′ and fourth 61′ burden of the electric circuit is picked up against the potential of the reference potential inputs. Hence, a differential voltage measurement is performed with which the difference voltage between the symmetrically arranged halves of the series connection 6 is measured. Due to the symmetry of the burdens 61, 62, 61′, 62′ relative to the point of symmetry 19, the two voltage values U and U′ may be identical.

In the connection combination of the current-measuring apparatus 100 shown in FIG. 6, a differential voltage measurement is performed in that the voltage U that drops across the second 62 burden of the electric circuit and the voltage U′ that drops across the third 62′ burden of the electric circuit is picked up against the potential of the reference potential inputs. Hence a differential voltage measurement is performed with which the difference voltage between the symmetrically arranged burdens 62, 62′ of the series connection 6 is measured. Due to the symmetry of the burdens 62, 62′ relative to the point of symmetry 19, the two voltage values U and U′ may be identical.

Depending upon the current intensity of the primary current to be measured, the connection combination in accordance with FIG. 5 is selected with four burdens connected to the electric circuit or the connection combination in accordance with FIG. 6 is selected with two burdens connected to the electric circuit.

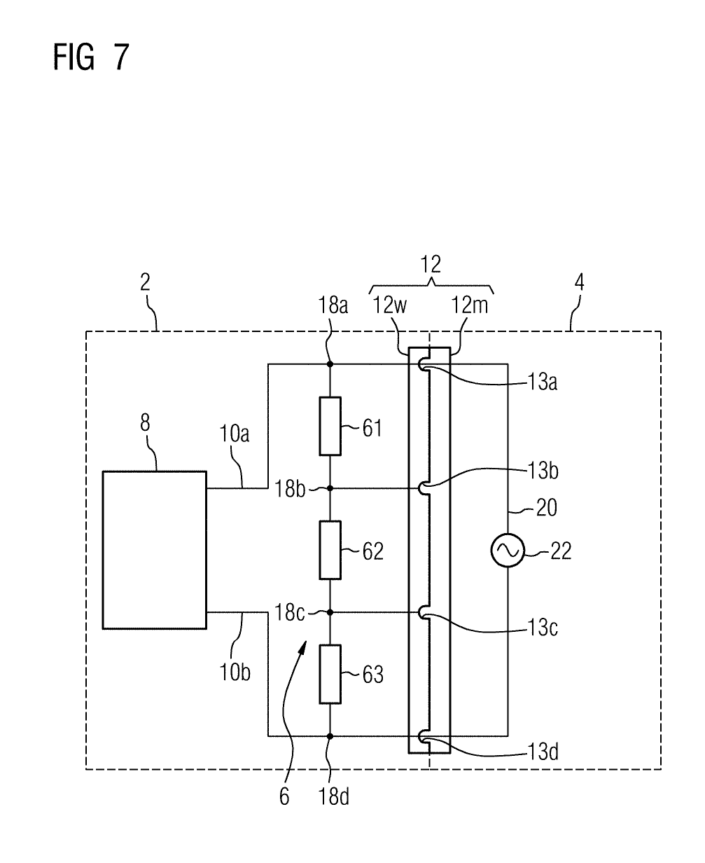

FIG. 7 depicts a variant of a current-measuring apparatus with an extended number of three burdens 61, 62, 62, with a plug-in connector 12 including four poles 13a, 13b, 13c, 13d. While, in the series shown in FIG. 4, two burdens 61, 62 are arranged in a series connection 6 in the assembly 2, with a plug-in connector 12 including three poles 13a, 13b, 13c, in the assembly 2 shown in FIG. 7, three burdens 61, 62, 63 are arranged in a series connection 6 with a plug-in connector 12 including four poles 13a, 13b, 13c, 13d.

Hence, in contrast to the series shown in FIG. 4, in which three connection combinations of the secondary coil 20 with the two burdens 61, 62 are possible, three further connection combinations of a secondary coil 20 with the three burdens 61, 62, 63 are possible.

Although the disclosure has been illustrated and described in detail by the exemplary embodiments, the disclosure is not restricted by the disclosed examples and the person skilled in the art may derive other variations from this without departing from the scope of protection of the disclosure. It is therefore intended that the foregoing description be regarded as illustrative rather than limiting, and that it be understood that all equivalents and/or combinations of embodiments are intended to be included in this description.

It is to be understood that the elements and features recited in the appended claims may be combined in different ways to produce new claims that likewise fall within the scope of the present disclosure. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

1. A current-measuring apparatus comprising:
an assembly having a plurality of burdens in series connection; and
a current transformer module having a secondary coil,
wherein the series connection comprises three or more contacts such that connection combinations of the secondary coil to, in each case, two of the three or more contacts provides for different groups of at least one burden of the plurality of burdens to be connected to the secondary coil to provide an electric circuit through which a secondary current induced in the secondary coil by a primary current to be measured is configured to flow.

2. The current-measuring apparatus of claim 1, further comprising:
a measurand-detection unit having measuring contacts configured to pick up a voltage that drops over at least two burdens of the plurality of burdens.

3. The current-measuring apparatus of claim 2, further comprising:
a plug-in connector having a plurality of poles configured to connect the current transformer module to the assembly.

4. The current-measuring apparatus of claim 3, wherein each burden of the plurality of burdens is connected in an electrically conductive manner to two poles of the plurality of poles of a part of the plug-in connector arranged on the assembly.

5. The current-measuring apparatus of claim 4, wherein the secondary coil of the current transformer module has an electrically conductive connection to two poles of the plurality of poles of the plug-in connector arranged on the current transformer module.

6. The current-measuring apparatus of claim 3, wherein the secondary coil of the current transformer module has an electrically conductive connection to two poles of the plurality of poles of a part of the plug-in connector arranged on the current transformer module.

7. The current-measuring apparatus of claim 1, further comprising:
a plug-in connector having a plurality of poles configured to connect the current transformer module to the assembly.

8. The current-measuring apparatus of claim 7, wherein each burden of the plurality of burdens is connected in an electrically conductive manner to two poles of the plurality of poles of a part of the plug-in connector arranged on the assembly.

9. The current-measuring apparatus of claim 8, wherein the secondary coil of the current transformer module has an electrically conductive connection to two poles of the plurality of poles of the plug-in connector arranged on the current transformer module.

10. The current-measuring apparatus of claim 7, wherein the secondary coil of the current transformer module has an electrically conductive connection to two poles of the plurality of poles of a part of the plug-in connector arranged on the current transformer module.

11. The current-measuring apparatus of claim 1, wherein the series connection comprises two or more pairs of burdens of the plurality of burdens with a same electrical resistance, and
wherein the two or more pairs of burdens are arranged symmetrically relative to a point of symmetry of the series connection.

12. A series of current-measuring apparatuses comprising:
at least two current-measuring apparatuses having:
an assembly having a plurality of burdens in series connection; and
a current transformer module having a secondary coil,
wherein the series connection comprises three or more contacts such that connection combinations of the secondary coil to, in each case, two of the three or more contacts provides for different groups of at least one burden of the plurality of burdens to be connected to the secondary coil to provide an electric circuit through which a secondary current induced in the secondary coil by a primary current to be measured is configured to flow
wherein each assembly of each current-measuring apparatus is configured to be connected to two or more different current transformer modules, and
wherein the two current-measuring apparatuses differ in at least one burden connected to the secondary coil to form the electric circuit.

13. A method for measuring current comprising:
providing an assembly having a plurality of burdens in series connection, wherein the series connection comprises three or more contacts;
providing a current transformer module having a secondary coil;
selecting a connection combination from of a plurality of possible connection combinations in which the secondary coil is connected, in each case, to two contacts of the three or more contacts such that at least one burden of the plurality of burdens forms an electric circuit with the secondary coil;
connecting the secondary coil to two of the three or more contacts in accordance with the selected connection combination;
positioning the secondary coil such that a secondary current induced in the secondary coil by a primary current to be measured in flows through the electric circuit;
measuring a voltage, which drops across at least two burdens of the plurality of burdens in the series connection; and
calculating a current value of the primary current from the measured voltage.
